(19) United States
(12) Patent Application Publication
(10) Pub. No.: US 2018/0143230 A1
(43) Pub. Date: May 24, 2018

(54) SYSTEM AND METHOD FOR PARALLEL POWER MONITORING

(71) Applicant: Google Inc., Mountain View, CA (US)

(72) Inventor: Jianyi Liu, Santa Clara, CA (US)

(21) Appl. No.: 15/702,226

(22) Filed: Sep. 12, 2017

Related U.S. Application Data
(60) Provisional application No. 62/425,414, filed on Nov. 22, 2016.

(51) Int. Cl. G01R 22/10; G01R 22/06

(52) U.S. Cl. CPC G01R 22/10; G01R 22/063

(57) ABSTRACT

One aspect of the disclosure provides a data acquisition system (“DAQ”) for monitoring, in parallel, the power consumption of a plurality of subsystems of a device under test (“DUT”). The DAQ comprises a plurality of power monitors and a field-programmable gate array (“FPGA”) chip. The power monitors are employed to gather the power consumption for the subsystems of the DUT. The FPGA chip can independently operate the power monitors via internal logic. By employing a parallel array of power monitors, power consumption data can be collected at the same time, and in some cases down to the tens of nanoseconds or less. Once the data is acquired by the FPGA chip, it timestamps, packages and sends the data to a host computer for further processing and/or presentation to a user.

### CROSS-REFERENCE TO RELATED APPLICATIONS

The present application claims the benefit of the filing date of U.S. Provisional Patent Application No. 62/425,414 filed Nov. 22, 2016, the disclosure of which is hereby incorporated herein by reference.

### BACKGROUND

As mobile devices become smaller and increasingly complex, it becomes especially important for engineers and developers to be able to accurately and effectively measure the power consumption of the products they are designing. Often, the commercial success of a mobile device is tied to the size of the device and its battery life. However, as devices get smaller, the size of the battery also must shrink. Thus, significant emphasis is often placed on the optimization of power consumption during product development.

Often, in order to successfully and accurately measure the power consumption of a device, a platform system is developed in parallel with the form factor device. This platform system must retain all the functionality of the device, while also providing access points for monitoring the power consumption of the various subsystems. Often, a data acquisition system (“DAQ”) is then used to gather and analyze the power consumption data. DAQs are widely available and used as a standard method of development in the mobile hardware industry. However, they are often expensive. Low end models usually costs several thousand U.S. dollars, and high-end models can be upwards of tens of thousands in U.S. dollars. As a result, a small development team may only have enough resources to obtain one or two DAQs. This presents several challenges to the team because the DAQs will need to be shared, which may increase setup times and possibly introduce measurement errors due to human error.

Furthermore, DAQs frequently utilize a sequential method of sampling. Sequential sampling creates a timing accuracy delta (differential) between the sampling of the first channel and the sampling of the last channel This timing accuracy delta can make it difficult to effectively analyze and correlate the power consumption data from the various sample points. Therefore, such DAQs are not effective when developing mobile devices that require the timing accuracy to be within, for example, 10 ns, and require the time sampling resolution to be much finer than, for example, 1 ms.

### BRIEF SUMMARY

The technology relates to a system and method for monitoring, in parallel, the power consumption of multiple subsystems of a device under test (“DUT”). Aspects of the technology provide highly accurate and affordable power sampling tools for monitoring the power consumption of a DUT. For instance, some embodiments provide one or more of the following: (1) the system is capable of monitoring, in parallel, the power consumption of numerous subsystems of a DUT, (2) the system is extremely cost efficient, (3) the timing resolution of the power consumption data collected by the system is finer than 1 ms, and (4) the timing accuracy of the power consumption data collected by the system is within 10 ns.

One aspect of the disclosure provides a power monitoring system comprising: (1) a plurality of sensors configured to measure real-time power consumption data of a plurality of subsystems of the device under test, (2) a first circuit including one or more temporary memories and a plurality of communications interfaces, wherein the plurality of communications interfaces are communicatively coupled to one or more of the sensors through a plurality of buses, and (3) one or more processing devices configured to: (a) prime the communications interfaces of the first circuit for data collection by sending instructions to the communications interfaces, and (b) broadcast a start command to the communications interfaces to cause the communications interfaces to: (i) obtain, in parallel, real-time power consumption data from the plurality of sensors, (ii) timestamp the real-time power consumption data obtained from the plurality of sensors, and (iii) store the timestamped real-time power consumption data in the one or more temporary memories of the first circuit.

Another aspect of the disclosure provides a method for monitoring power comprising: (1) priming a plurality of communications interfaces, communicatively coupled to one or more sensors through a plurality of buses for data collection, by sending instructions to the communications interfaces; and (2) broadcasting a start command to the communications interfaces that causes the communications interfaces to: (a) obtain, in parallel, real-time power consumption data for a plurality of subsystems of a device under test from the one or more sensors; (b) timestamp the real-time power consumption data obtained from the plurality of sensors; and (c) store the timestamped real-time power consumption data in the one or more temporary memories of the first circuit.

### BRIEF DESCRIPTION OF THE DRAWINGS

FIG. 1 illustrates a conventional system for gathering power consumption data for a plurality of subsystems of a DUT.

FIG. 2 illustrates a system for monitoring, in parallel, the power consumption of a plurality of subsystems of a DUT according to aspects of the disclosure.

FIG. 3 illustrates a system for monitoring, in parallel, the power consumption of a plurality of subsystems of a DUT according to aspects of the disclosure.

FIG. 4 illustrates an example power consumption monitor for a particular subsystem of a DUT according to aspects of the disclosure.

FIG. 5 illustrates an I2C communications scheme with a single I2C bus according to aspects of the disclosure.

FIG. 6 illustrates an I2C communications scheme with two I2C buses according to aspects of the disclosure.

FIG. 7 illustrates an I2C communications scheme with four I2C buses according to aspects of the disclosure.

FIG. 8 illustrates an FPGA chip configured to collect, process, and forward power consumption data to a host computer when using the communications scheme of FIG. 7 according to aspects of the disclosure.

FIG. 9 illustrates a method for monitoring power according to aspects of the disclosure.

### DETAILED DESCRIPTION

Aspects, features and advantages of the disclosure will be appreciated when considered with reference to the following description of embodiments and accompanying figures. The same reference numbers in different drawings may identify the same or similar elements. Furthermore, the following description is not limiting; the scope of the present technology is defined by the appended claims and equivalents. For example, while certain processes may be shown in the figures as occurring in a linear fashion, this is not a requirement unless expressly stated herein. Different processes may be performed in a different order or concurrently. Steps may also be added or omitted unless otherwise stated.

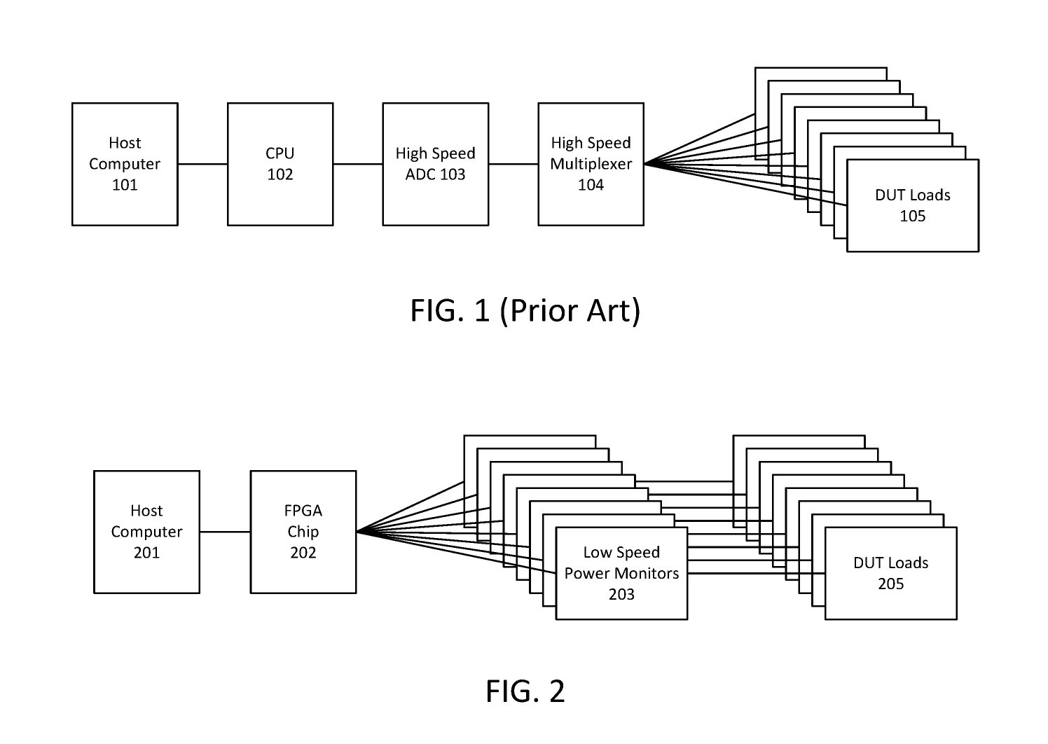

FIG. 1 illustrates a conventional system for gathering power consumption data for a DUT with multiple subsystems of interest (e.g., DUT loads 105). DAQs may typically contain between one and four high speed analogue-to-digital converters (“ADCs”) and one very high speed multiplexer. As shown in FIG. 1, a conventional DAQ may include a host computer 101, a computing device 102, a high speed ADC 103, and a high speed multiplexer 104. High speed multiplexer 104 is used to change the sampling inputs of high speed ADC 103 in a sequential fashion. High speed ADC 103 is then used to measure, for example, the shunt and bus voltages associated with DUT loads 105.

The sequential nature of this sampling scheme may introduce a problematic measurement error. As noted above, there is a time delta between the measurement of the voltages of the first DUT load and the voltages of the last DUT load. The value of this time delta changes depending on the specific application and the number of DUT loads. For example, when a DAQ is used to monitor the power consumption of only two DUT loads, the time delta may be very small because the high speed ADC and the high speed multiplexer only need to switch between four channels (e.g., two shunt voltages and two bus voltages). However, when a DAQ is used to monitor, for example, 40 DUT loads, the time delta may be quite significant, (e.g., greater than 100 ns) because the high speed multiplexer needs to switch between 80 channels. Time deltas of this magnitude, or otherwise in excess of 10 ns, make it very difficult to properly reconstruct the overall power consumption of a DUT. Such reconstruction may be computationally expensive or introduce other delays into the system. Reconstruction may also introduce artifacts and errors into the data.

The ability to gather power consumption data with a high degree of timing accuracy can be very important to designing certain complex systems. For example, in a camera system with an LED flash, it is extremely useful to understand how much lead time is necessary for the LED to turn on before the camera shutter can be opened. Any extra time that the LED is turned on results in wasted power. With a parallel power monitoring system, an engineer or developer could effectively optimize this type of a problem. However, with a sequential power monitoring system, this optimization problem becomes much more challenging to solve because of the time delta error.

FIG. 2 illustrates an example system for monitoring, in parallel, the power consumption of a plurality of subsystems of a DUT. As shown in FIG. 2, a plurality of low speed power monitors 203 are employed to gather the power consumption for respective DUT loads 205. The field-programmable gate array (“FPGA”) chip 202 is configured to independently operate the plurality of low speed power monitors 203 via internal logic. By employing a parallel array of power monitors in this manner, power consumption data can be collected at the same time, and in some cases down to the tens of nanoseconds or less. Once the data is acquired by the FPGA chip 202, it timestamps, packages and sends the data to the host computer 201 for further processing and/or presentation to a user.

Since the data is not collected in a sequential manner, it is not subject to the time delta discussed with reference to FIG. 1. Furthermore, the data can be collected without the use of an expensive high speed ADC or an expensive high speed multiplexer. Thus, the cost of the device of FIG. 2 can be significantly less than the cost of the device of FIG. 1. As a result, a small development team may be able to obtain a sufficient number of DAQs as shown in FIG. 2 for each member of the team.

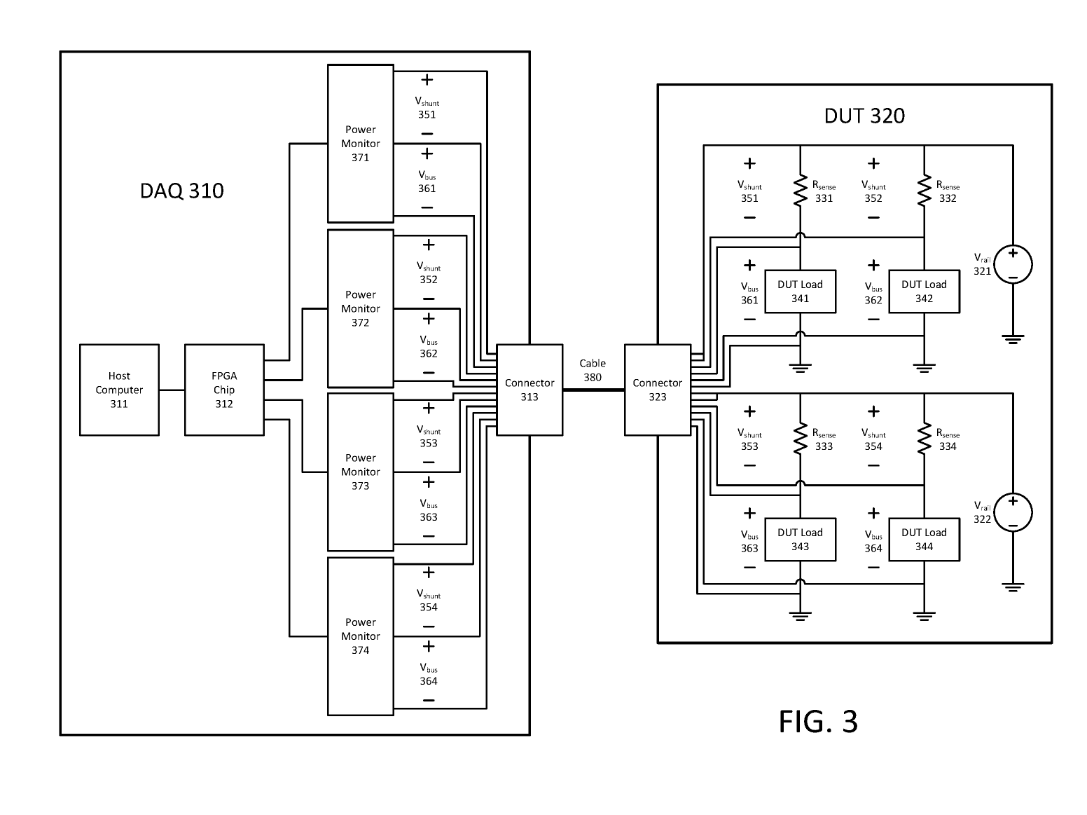

FIG. 3 depicts a system similar to that shown in FIG. 2. In FIG. 3, DAQ 310 is used to monitor the power consumption of various subsystems of DUT 320 (e.g., DUT loads 341-344). The DUT loads 341-344 of DUT 320 are powered by voltage sources 321 and 322. Voltage sources 321 and 322 may comprise batteries, AC sources, and/or additional circuitry for regulating the output voltages from the batteries and/or AC sources. DAQ 310 and DUT 320 are communicatively coupled through connectors 313 and 323 and intervening cable 380. In one example, cable 380 may be a ribbon cable and connectors 313 and 323 may be male or female header connectors.

DAQ 310 comprises a host computer 311, an FPGA chip 312, and power monitors 371-374. The power monitors 371-374 are used to monitor the power consumption of DUT loads 341-344. This may be accomplished, in part, by monitoring the voltages across sense resistors 331-334 (e.g., shunt voltages 351-354) and the voltages across DUT loads 341-344 (e.g., bus voltages 161-164). Power monitors 371-374 may be implemented using a chip such as the Texas Instruments INA226 chip, which is a current shunt and power monitor with an I2C interface. FPGA chip 312 may be implemented using a chip such as a Xilinx XC7A100T chip. Host computer 311 may be used for displaying and analyzing the power consumption data of DUT Loads 341-344.

Other variations of the embodiment depicted in FIG. 3 may be employed. For example, DUT 320 may include forty or more subsystems of interest and DAQ 310 may have a corresponding amount of power monitors. In another example, FPGA chip 312 can be replaced altogether with a system-on-chip (“SoC”), a microcontroller, a custom application-specific integrated circuit (“ASIC”), or an equivalent processing element. In yet another example, the functionality of power monitors 371-374 may be incorporated into a single FPGA chip or a single custom ASIC. Power monitors 371-374 can also be replaced with a plurality of less specialized components such as, for example, analogue-to-digital converters (“ADCs”) and serial protocol interface chips.

Furthermore, numerous communication interfaces or standards can be utilized between host computer 311 and FPGA chip 312. For example, FPGA chip 312 may communicate with host computer 311 through any one of the following types of interfaces: USB, Ethernet, RS-232, Serial Peripheral Interface (“SPI”), I2C, or a custom-defined communications interface. FPGA chip 112 may also communicate with host computer 311 wirelessly through, for example, WiFi, Bluetooth, ZigBee, or a custom-defined wireless communications protocol. Similarly, numerous communication interfaces or standards can be utilized between FPGA chip 312 and power monitors 371-374.

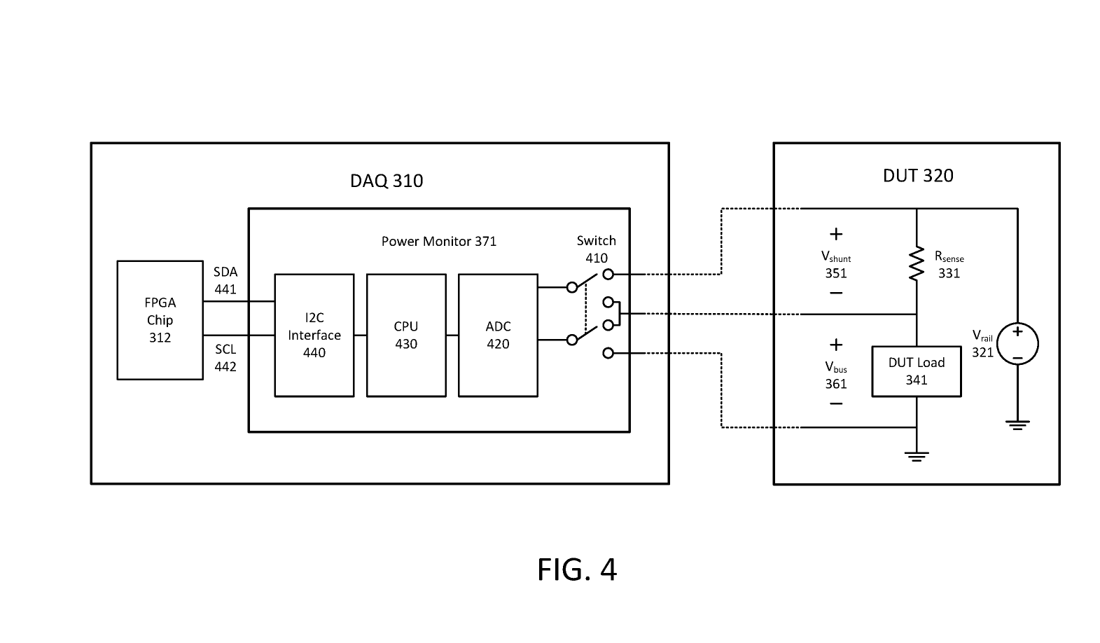

FIG. 4 demonstrates how one of the power monitors (e.g., power monitor 371) of the DAQ 310 can be used to monitor the power consumption of a particular subsystem (e.g., DUT load 341) of the DUT 320. In this example, a low resistance, high accuracy resistor (e.g., sense resistor 331) is placed in series with the DUT Load 341. When current is applied to sense resistor 331, the DUT load 341 is powered and fully functional. By using the changes in the small differential voltage created across the sense resistor 331 (e.g., shunt voltage 351) in conjunction with the voltage applied to the DUT load 341 (e.g., bus voltage 361), the following equations can be used to determine the power consumption of the DUT load 341:

$$Current = \frac{{V}_{shunt}}{{R}_{sense}}$$

$$Power = \frac{{V}_{bus} \times {V}_{shunt}}{{R}_{sense}}$$

In order to process this information digitally, the internal ADC 420 may be used to sample the shunt voltage 351 and the bus voltage 361. Switch 410 may be used to change the sampling inputs to the ADC 420. Furthermore, the information obtained from the ADC 420 may be processed by computing device 430, and then serialized by I2C Interface 440 before it is sent to, for example, the FPGA chip 312. SDA 441 and SCL 442 are the data and clocking lines that form the I2C bus between the power monitor 371 and the FPGA chip 312.

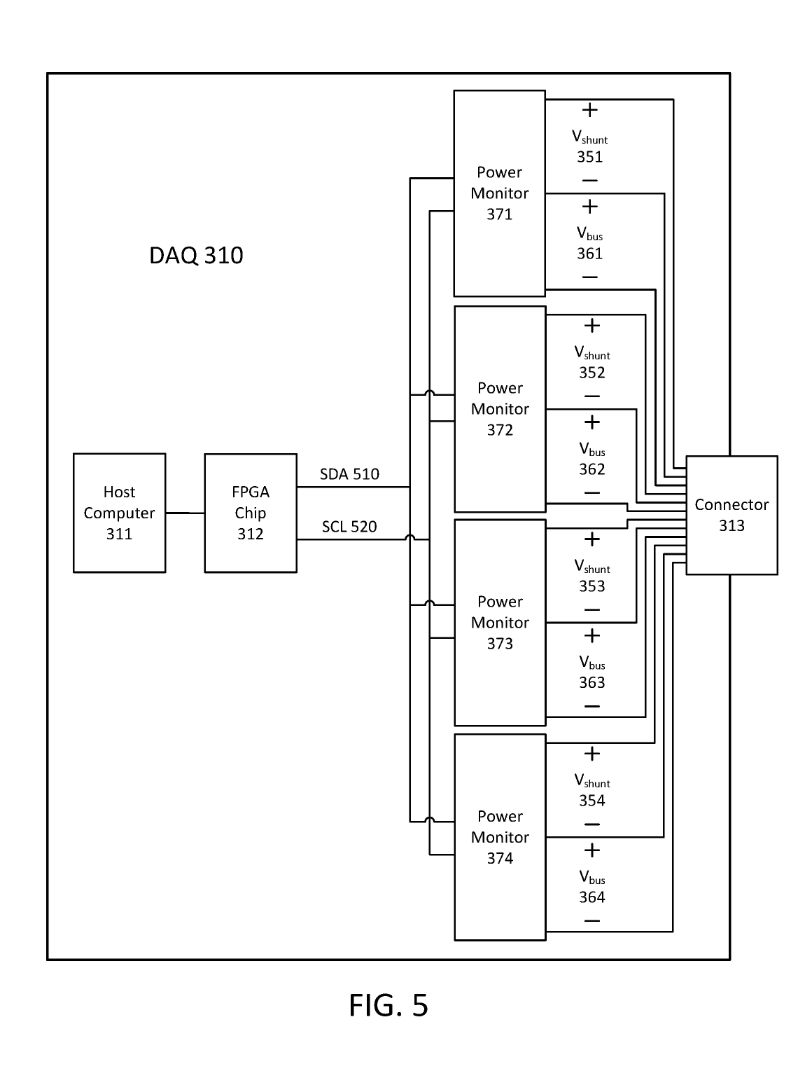

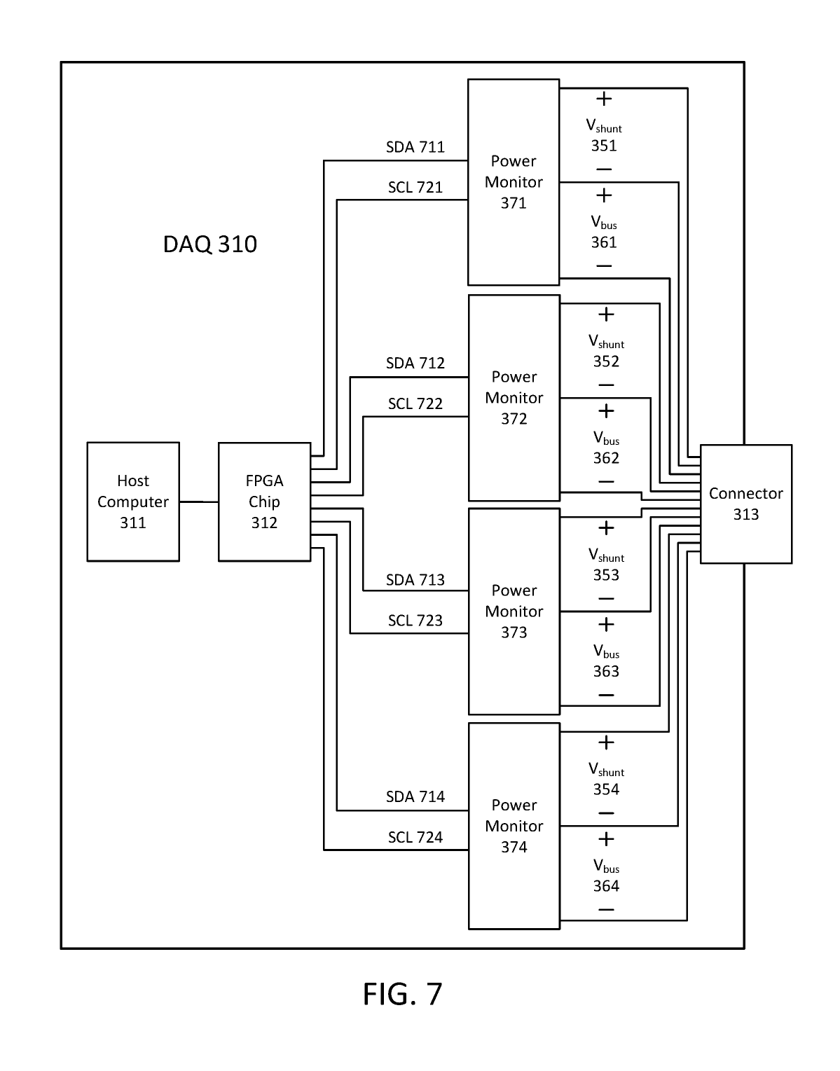

FIGS. 5-7 demonstrate the advantages of using a plurality of buses (as opposed to a single bus) between the FPGA chip 312 and power monitors 371-374. Although the I2C communications standard is used in these examples, the benefits of using multiple buses can be realized when using many other standards or interfaces. Furthermore, for simplicity and clarity, FIGS. 5-7 continue to illustrate variations of the DAQ 310 of FIG. 1, which only has four power monitors. However, the advantages of the system of FIG. 7 as compared to, for example, the system of FIG. 5 become more apparent as the number of power monitors is increased.

FIG. 5 depicts an I2C communications scheme where a single I2C bus comprising SDA 510 and SCL 520 is shared by the FPGA chip 312 and power monitors 371-374. In this setup, aside from being able to send a simple broadcast signal, the FPGA chip 312 cannot communicate with all of power monitors 371-374 at the same time. Instead, the FPGA chip 312 polls each of power monitors 371-374 individually. Therefore, by implementing the DAQ 310 of FIG. 1 with only a single bus between the FPGA chip 312 and power monitors 371-374, the FPGA chip 312 is not be able to collect power consumption data in parallel. Instead, the FPGA chip 312 would have to waste valuable time polling each of power monitors 371-374 individually. Thus, the polling process limits the amount of data that the FPGA chip 312 can collect over time.

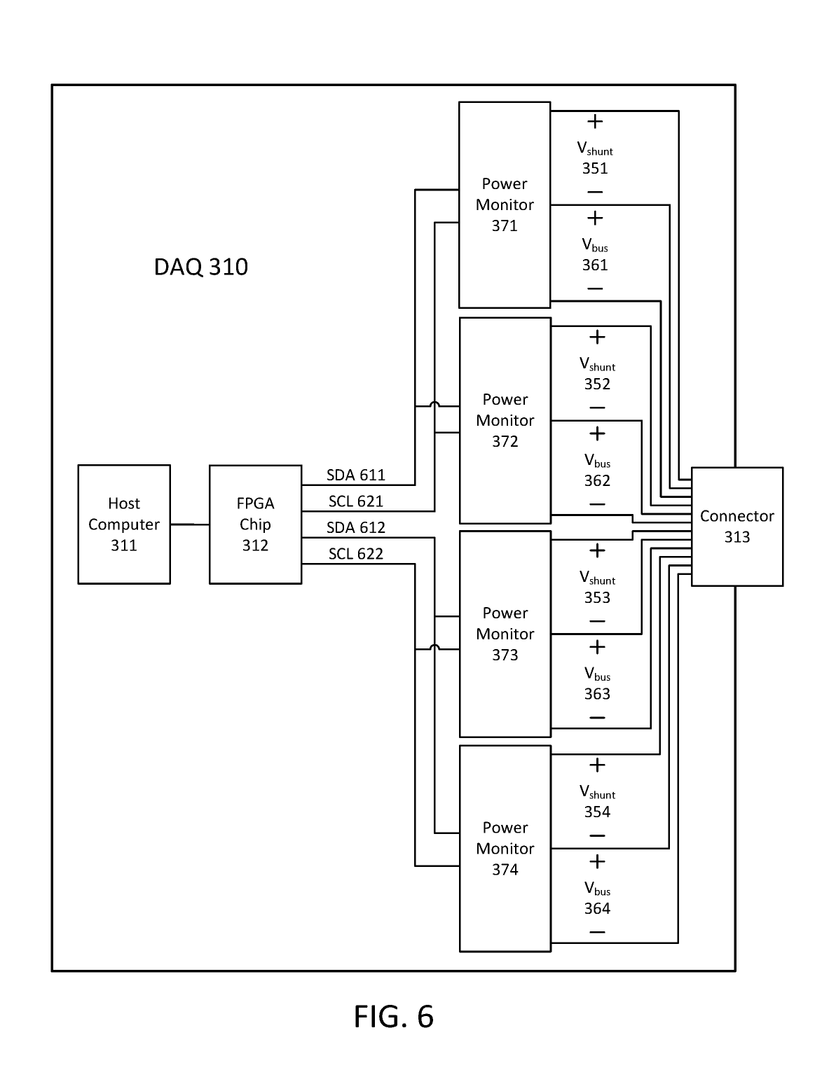

FIG. 6 depicts another I2C communications scheme that could be implemented between the FPGA chip 312 and power monitors 371-374. In FIG. 6, there is a first I2C bus comprising SDA 611 and SCL 621, and a second I2C bus comprising SDA 612 and SCL 622. In this setup, power monitors 371 and 371 are connected to the first I2C bus and power monitors 373 and 374 are connected to the second bus. Therefore, although mitigated, the same traffic restrictions discussed with reference to FIG. 5 are present. However, unlike the embodiment of FIG. 5, the FPGA chip 312 of FIG. 6 does not have to individually poll all of power monitors 371-374. Instead, the FPGA chip 312 can simultaneously poll two of power monitors 371-374 at the same time through the two I2C buses. Therefore, this system can provide a higher degree of timing accuracy and resolution than the system of FIG. 5.

FIG. 7 depicts yet another I2C communications scheme that could be implemented between the FPGA chip 312 and power monitors 371-374. In FIG. 7, each of power monitors 371-374 has a separate dedicated I2C bus to communicate with the FPGA chip 312. Specifically, power monitors 371-374 can use SDA 711-714 and SCL 721-724 respectively to communicate with the FPGA chip 312. In this setup, the FPGA chip can simultaneously communicate with all of power monitors 371-374. Therefore, this system can provide a higher degree of timing accuracy and resolution than the systems of FIGS. 5 and 6.

As mentioned above, the FPGA chip 312 in any one of FIGS. 5-7 can be replaced altogether with an SoC or a microcontroller. Some readily commercially available SoCs may have between three and five I2C interfaces, whereas others may have between eight and ten I2C interfaces. However, a typical SoC executing code in a sequential fashion can only interact with one I2C interface at a time. Custom drivers can be used to reduce, but not completely eliminate, this time delta. In contrast, as discussed in more detail below, the I2C interfaces of an FPGA chip can be configured to initiate communications with I2C devices, such as power monitors 371-374, at essentially the same time. For example, depending on the input clock rate, an FPGA chip may be able to initiate communications with over 40 different I2C devices within 10 ns, 4 ns, or even 2 ns.

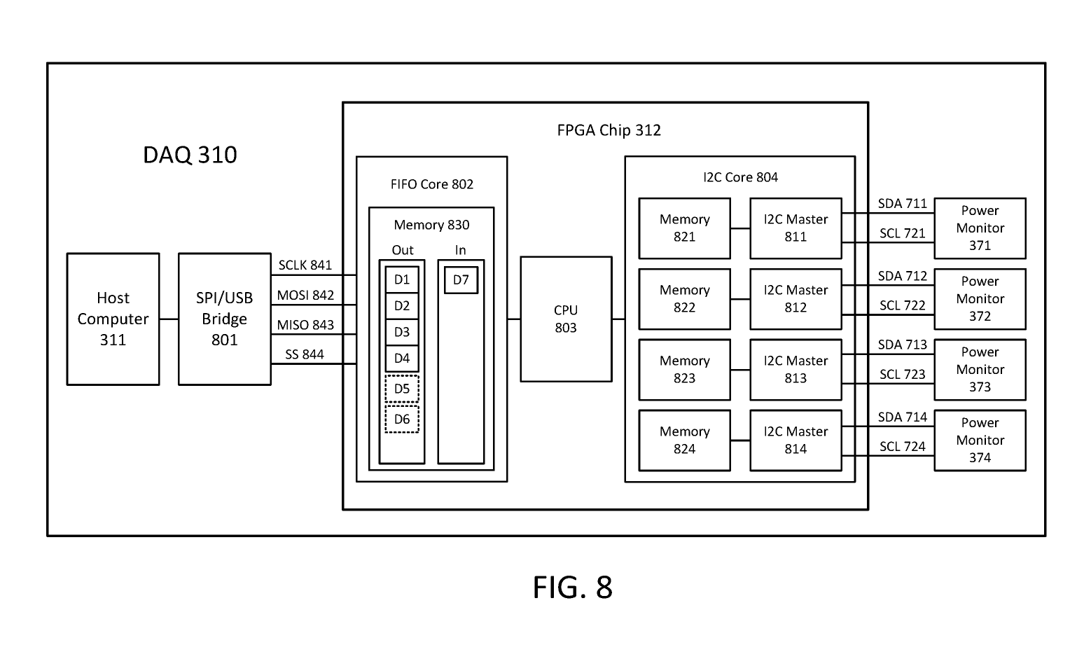

FIG. 8 illustrates how power consumption data can be collected, processed, and forwarded to the host computer 311 by the FPGA chip 312 when using the communications scheme of FIG. 7. As shown in FIG. 8, the FPGA chip 312 need not communicate directly with the host computer 311. Instead, as shown, the FPGA chip 312 communicates with SPI/USB bridge 801 through an SPI interface. The SPI bus between the two devices comprises SCLK 841 (e.g., a serial clock line), MOSI 842 (e.g., a master output, slave input line), MISO 843 (e.g., a master input, slave output line), and SS 844 (e.g., a slave select line). The SPI/USB bridge 801 converts the serialized data received from the FPGA chip 312 and forwards it to the host computer 311 through a USB interface. The SPI/USB bridge 801 may be, for instance, an FTDI FT2232H Dual High Speed USB to Multipurpose UART/FIFO IC. In other embodiments, the FPGA chip and the USB bridge may be integrated into one chip. Furthermore, other communication interfaces or standards can be utilized between the host computer 311 and the FPGA chip 312. For example, the FPGA chip may forward the data to an Ethernet bridge through an I2C interface. The Ethernet bridge may then covert and forward the data to the host computer.

As shown in FIG. 8, the FPGA chip 312 has a computing device 803, an I2C core 804, and a FIFO core 802. The cores may be blocks of logic and/or source code with read/write instructions and temporary storage memory. The I2C core 804 includes I2C masters 811-814 and memories 821-824. The FIFO core 802 includes a memory 830, which has a data-in buffer and a data-out buffer. As shown in FIG. 8, the data-in buffer of the memory 830 contains six segments of data (e.g., D1-D6) and the data-out buffer of the memory 830 contains one segment of data (e.g., D7). In this example, data segments D5 and D6 are shown in boxes with dashed lines because computing device 803 is in the process of writing those segments of data to the memory 830.

The I2C core 804 retrieves, timestamps, and stores the power consumption data received from power monitors 371-374 in temporary memory. As shown in FIG. 8, each of the I2C masters 811-814 has its own temporary memory (e.g., memories 821-824). However, memories 821-824 can be combined or shared amongst the I2C masters 811-814. In this setup, computing device 803 can sequentially configure the I2C masters 811-814 of the I2C core 804 to perform individualized sets of instructions. During operation, the computing device 803 may update or change these instructions. These instructions prime the I2C masters 811-814, but they do not cause the I2C masters 811-814 to initiate communications with power monitors 371-374. Instead, the I2C masters 811-814 wait for the computing device 803 to broadcast a “start” command Once this start command is received, each of the I2C masters 811-814 start to engage the I2C buses and perform the instructions to the I2C slaves (e.g., power monitors 371-374). For a write instruction, an I2C master sends a sequence of information. For a read instruction, the I2C master sends a sequence of information, and then receives a sequence of information. The power consumption data received from power monitors 371-374 can be stored and timestamped in memories 821-824. The timestamp may correspond with when the start command was sent by the computing device 803.

By timestamping the data, the computing device 803 can retrieve the data stored in memories 821-824 without creating a timing delta. After retrieving the power consumption data from memories 821-824 of the I2C core 804, the computing device 803 can process the data and store it in the out-data buffer of the FIFO core 802. For example, if power monitors 371-374 simply provide data concerning the shunt and the bus voltages, the computing device 803 may perform the calculations discussed above with reference to FIG. 4 to determine the power consumed by the DUT loads of interest.

The FIFO core 802 automatically handles the timing protocols and resources needed to package and transmit the power consumption data to the host computer 311. The computing device 803 needs to process and transmit the power consumption data obtained from the I2C core 804 very quickly and it does not have the computational resources to wait around for the next polling packet from the host computer 311. Therefore, the FIFO core 802 automatically handles these processes. The memory of the FIFO core 802 should be large enough to store all of the data generated during an especially long or extended polling period of the host computer 311. For example, since a USB bulk data transfer is asynchronous, there can be large variations in polling periods. Furthermore, for non-real time operating systems, such as Windows and Linux, polling periods can vary, especially when the host computer is performing heavy computations. Therefore, in an embodiment where packets of data are generated by the FPGA chip 312 every 1 ms, and each of those packets has a length of approximately 273 bytes, it may be appropriate to allocate at least 8192 bytes to each of the buffers in the memory 830. In such an embodiment, a polling period may be upwards of 20+/−10% ms. Therefore, it would be advantageous to be able to store at least 30+/−10% ms of data in the memory 830 of the FIFO core 802.

In order to guarantee that no packets of data are lost, the FIFO core 802 may include a locking mechanism that locks out the consumption of the data during any SPI traffic (for both directions). Because the amount of data written into the memory 830 of the FIFO core 802 is high, it might take some time before a full write operation can finish. As a result, if the computing device 803 is pushing data into the data-out buffer of the memory 830 and the USB/SPI bridge 801 is pulling out data, there might be a situation where there is a race condition. This can be avoided by including a locking mechanism. As shown in FIG. 8, the computing device 803 is in the process of writing D5 and D6 into the data-out buffer of memory 830. As soon as this write operation is initiated, the locking mechanism is triggered and it prevents the USB/SPI bridge 801 from trying to retrieve D5 and D6. Instead, the USB/SPI bridge 801 can only retrieve D1-D4. Once the computing device 803 completes the write operation, D5 and D6 will be made available to the USB/SPI bridge 801. A similar locking mechanism can be implemented for the data-in buffer of memory 830. However, that locking mechanism would be triggered when the USB/SPI bridge 801 begins to write new data to the data-in buffer of the memory 830.

It is also possible combine memories 821-824 and 830. For example, the I2C masters 811-814 could store the raw data received from power monitors 371-374 in the data-out buffer of the memory 830. However, there is some benefit to processing the data first. For example, by using the computing device 803 to perform some of the calculations discussed above with reference to FIG. 4, the required amount of computational resources of the host computer 311 can be minimized Furthermore, the raw data might not be useful directly. For example, some of the raw data may be code, which requires a lookup table to decode. Therefore, it may be advantageous to perform this type of decode operation in the FPGA chip 312 before sending the data back to the host computer 311.

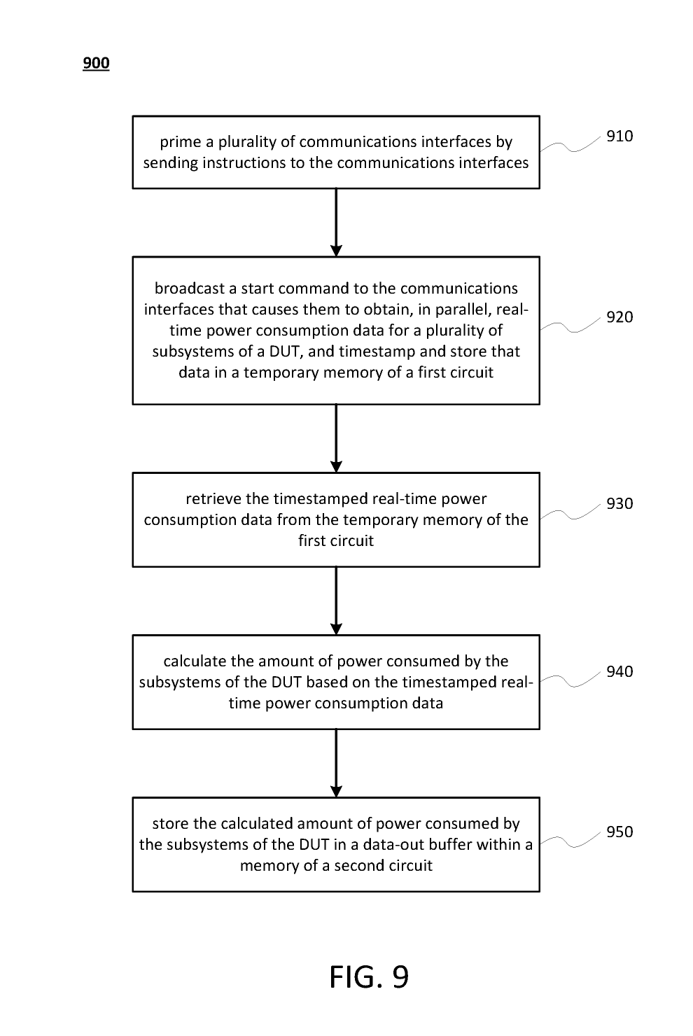

FIG. 9 illustrates a method 900 in accordance with the present technology. The method 900 may be implemented by a system including, for example, one or more processing devices, a first circuit, and a second circuit. While operations of the method 900 are described in a particular order below, it should be understood that the order of the operations may be modified. Moreover, some operations may be performed simultaneously. Further, operations may be added or omitted.

In block 910, the one or more processing devices prime a plurality of communications interfaces (e.g., I2C masters) by sending instructions to the communications interfaces. The one or more processing devices can prime the communications interfaces in a sequential manner These instructions prime the communications interfaces, but they do not cause them to initiate communications with, for example, a plurality of sensors communicatively coupled to the communications interfaces through a plurality of buses (e.g., power monitors).

In block 920, the one or more processing devices broadcast a start command to the communications interfaces that causes them to obtain, in parallel, real-time power consumption data from a plurality of sensors configured to measure real-time power consumption data of a plurality of subsystems of a DUT. The received power consumption data can be stored and timestamped in one or more temporary memories of a first circuit (e.g., the memories associated with the communications interfaces). The timestamps may correspond with when the start command was sent by the one or more processing devices.

In blocks 930 and 940, the one or more processing devices retrieve the timestamped real-time power consumption data from the one or more temporary memories of the first circuit and calculate the amount of power consumed by the subsystems of the DUT based on the retrieved data. For example, if the sensors simply provide data concerning the shunt and the bus voltages associated with the plurality of subsystems of the DUT, the one or more processing devices may perform the calculations discussed above with reference to FIG. 4 to determine the power consumed by these subsystems.

In block 950, the one or more processing devices store the calculated amount of power consumed by the subsystems of the DUT in a data-out buffer within a memory (e.g., a FIFO buffer) of a second circuit. The second circuit can then automatically handle the timing protocols and resources needed to package and transmit the real-time power consumption data to, for example, a host computer.

While the examples above describe monitoring components of a DUT, it should be understood that the techniques and principles described in the examples may similarly be applied in monitoring components of multiple DUTs at a given time. As these and other variations and combinations of the features discussed above can be utilized without departing from the disclosure as defined by the claims, the foregoing description of the embodiments should be taken by way of illustration rather than by way of limitation of the disclosure as defined by the claims. It will also be understood that the provision of examples of the disclosure (as well as clauses phrased as “such as,” “e.g.”, “including” and the like) should not be interpreted as limiting the disclosure to the specific examples; rather, the examples are intended to illustrate only some of many possible embodiments.

1. A power monitoring system for a device under test, the system comprising:
a plurality of sensors configured to measure real-time power consumption data of a plurality of subsystems of the device under test;
a first circuit including one or more temporary memories and a plurality of communications interfaces, wherein the plurality of communications interfaces are communicatively coupled to one or more of the sensors through a plurality of buses; and
one or more processing devices configured to:
prime the communications interfaces of the first circuit for data collection by sending instructions to the communications interfaces; and
broadcast a start command to the communications interfaces to cause the communications interfaces to:
obtain, in parallel, real-time power consumption data from the plurality of sensors;
timestamp the real-time power consumption data obtained from the plurality of sensors; and
store the timestamped real-time power consumption data in the one or more temporary memories of the first circuit.

2. The system of claim 1, wherein the sensors are configured to monitor one or more of shunt voltages and bus voltages associated with the subsystems of the device under test.

3. The system of claim 1, wherein each of the communications interfaces is communicatively coupled to only one of the plurality of sensors.

4. The system of claim 3, wherein the sensors are power monitors, and wherein each of the power monitors measure a shunt voltage and a bus voltage associated with only one of the subsystems of the device under test.

5. The system of claim 1, further comprising:
a second circuit including a memory with a data-in buffer and a data-out buffer, wherein the second circuit automatically handles timing protocols and resources to package and transmit the timestamped real-time power consumption data to a host computer communicatively coupled to the system.

6. The system of claim 5, wherein the first and second circuits are cores of a field-programmable gate array chip.

7. The system of claim 5, wherein the one or more processing devices are further configured to:
retrieve the timestamped real-time power consumption data from the one or more temporary memories of the first circuit;
calculate the amount of power consumed by the subsystems of the device under test based on the timestamped real-time power consumption data; and
store the calculated amount of power consumed by the subsystems of the device under test in the data-out buffer of the second circuit.

8. The system of claim 5, wherein the second circuit further includes a locking mechanism configured to:
prevent a device communicatively coupled to the second circuit from reading data that has been partially written into the data-out buffer by the one or more processing devices; and
prevent the one or more processing devices from reading data that has been partially written into the data-in buffer by the device communicatively coupled to the second circuit.

9. The system of claim 5, wherein the data-out buffer of the second circuit is large enough to store all of the power consumption data gathered by the system during an extended polling period of the host computer.

10. The system of claim 9, wherein the extended polling period is between about 20 ms and 30 ms.

11. A method for monitoring power, the method comprising:
priming a plurality of communications interfaces, communicatively coupled to one or more sensors through a plurality of buses for data collection, by sending instructions to the communications interfaces; and
broadcasting a start command to the communications interfaces that causes the communications interfaces to:
obtain, in parallel, real-time power consumption data for a plurality of subsystems of a device under test from the one or more sensors;
timestamp the real-time power consumption data obtained from the plurality of sensors; and
store the timestamped real-time power consumption data in the one or more temporary memories of the first circuit.

12. The method of claim 11, wherein the sensors are configured to monitor one or more of shunt voltages and bus voltages associated with the subsystems of the device under test.

13. The method of claim 11, wherein each of the communications interfaces is communicatively coupled to only one of the sensors.

14. The method of claim 13, wherein the sensors are power monitors, and wherein each of the power monitors measure a shunt voltage and a bus voltage associated with only one of the subsystems of the device under test.

15. The method of claim 11, further comprising:
retrieving the timestamped real-time power consumption data from the one or more temporary memories of the first circuit;
calculating the amount of power consumed by the subsystems of the device under test based on the timestamped real-time power consumption data; and
storing the calculated amount of power consumed by the subsystems of the device under test in a data-out buffer within a memory of a second circuit.

16. The method of claim 15, wherein the second circuit automatically handles the timing protocols and resources needed to package and transmit the timestamped real-time power consumption data to a host computer.

17. The method of claim 16, wherein the first and second circuits are cores of a field-programmable gate array chip.

18. The method of claim 16, wherein the second circuit further includes a locking mechanism configured to:
prevent a first device communicatively coupled to the second circuit from reading data that has been partially written into the data-out buffer; and
prevent a second device communicatively coupled to the second circuit from reading data that has been partially written into a data-in buffer within the memory of the second circuit.

19. The system of claim 16, wherein the data-out buffer of the second circuit is large enough to store all of the power consumption data gathered during an extended polling period of the host computer.

20. The system of claim 19, wherein the extended polling period is between about 20 ms and 30 ms.
